(19) United States
(12) Patent Application Publication
(10) Pub. No.: US 2018/0323708 A1
(43) Pub. Date: Nov. 8, 2018

(54) INTEGRATED VOLTAGE REGULATOR WITH AUGMENTED CURRENT SOURCE

(71) Applicant: Intel Corporation, Santa Clara, CA (US)

(72) Inventors: William J. LAMBERT, Chandler, AZ (US); Mathew MANUSHAROW, Phoenix, AZ (US)

(21) Appl. No.: 15/772,487

(22) PCT Filed: Dec. 22, 2015
(86) PCT No.: PCT/US2015/067401

§ 371 Date: Apr. 30, 2018

(51) Int. Cl. H02M 3/155

(52) U.S. Cl. CPC H02M 3/155; H05K 2201/10719; H05K 2201/10166; H05K 1/181; H05K 2201/1003; H05K 2201/10674; H05K 2201/10159; H05K 2201/10015

(57) ABSTRACT

A printed circuit board (PCB) includes one or more voltage rails and an integrated voltage regulator (IVR) electrically coupled to supply current to a voltage rail. The PCB also includes a PCB current source electrically coupled to supply a supplementary current to the voltage rail.

### FIELD

The present disclosure generally relates to integrated circuit (IC) voltage regulation.

### BACKGROUND

Current integrated circuit (IC) products, such as central processing units (CPUs) often implement integrated voltage regulators (IVRs) for IC voltage supply. IVRs are directly placed on the IC, which provides for more control of power IC management. However there are disadvantages to using IVRs. One such disadvantage is that power dissipation by the IVR occurs on the die itself, which directly subtracts from an IC's thermal budget. For example, a typical IVR delivering 24 A to the IC circuits at 1V output would result in the compute circuitry dissipating 24 W of power and the IVR will dissipating 4.69 W of power, for a conversion efficiency of 83.6%. Therefore, the CPU would dissipate 28.69 W to supply a 24 W load due to the efficiency of the IVR.

This is in contrast to a Motherboard Voltage Regulator (MBVR) in which the heat is dissipated some distance from the CPU and does not subtract from the CPU thermal budget. In many cases, the net benefits of an IVR will still preclude a MBVR from being used.

Another disadvantage is that in some FIVR implementations it may be necessary to grow the CPU die to enable a large enough FIVR to support the voltage domain's maximum possible operating current (Iₘₐₓ), which adds to the financial costs to produce an IC.

### BRIEF DESCRIPTION OF THE DRAWINGS

FIG. 1 illustrates one embodiment of a printed circuit board (PCB).

FIGS. 2A & 2B illustrate embodiments of a FIVR voltage rail;

FIG. 3 illustrates one embodiment of a FIVR packaging configuration.

FIG. 4 illustrates one embodiment of a current source.

FIG. 5 illustrates one embodiment of a computer system.

FIG. 6 illustrates a schematic side view representation of another embodiment system suitable to assemble a substrate;

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention.

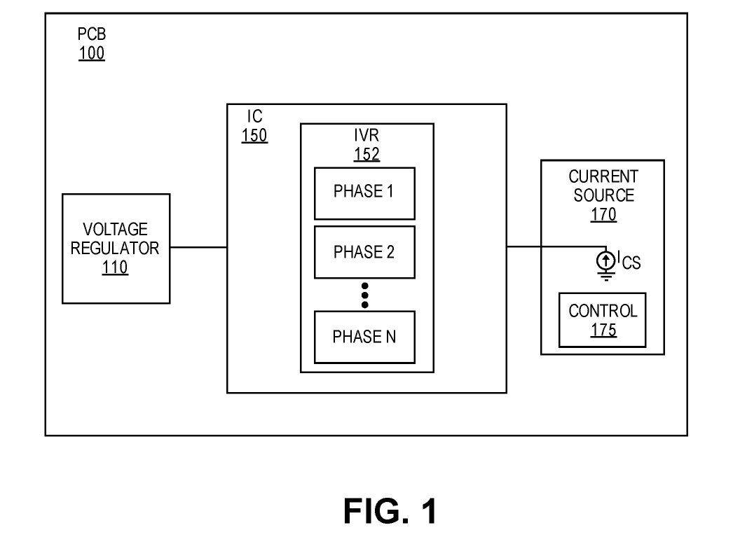

FIG. 1 illustrates one embodiment of a PCB 100. In one embodiment, PCB 100 is a motherboard that includes a voltage regulator 110, IC 150 and current source 170. Voltage regulator (VR) 110 provides an appropriate supply voltage to PCB 100 by converting +5V or +12V to a lower voltage (e.g., +1.5V) required by IC 150. IC 150 is electrically coupled to VR 110 via one or more pins on an electronics package (e.g., land grid arrays (LGAs)). In some embodiments IC 150 may be implemented as a microprocessor package. In such embodiments, the IC 150 package is similar to a PCB, though with finer dimensions.

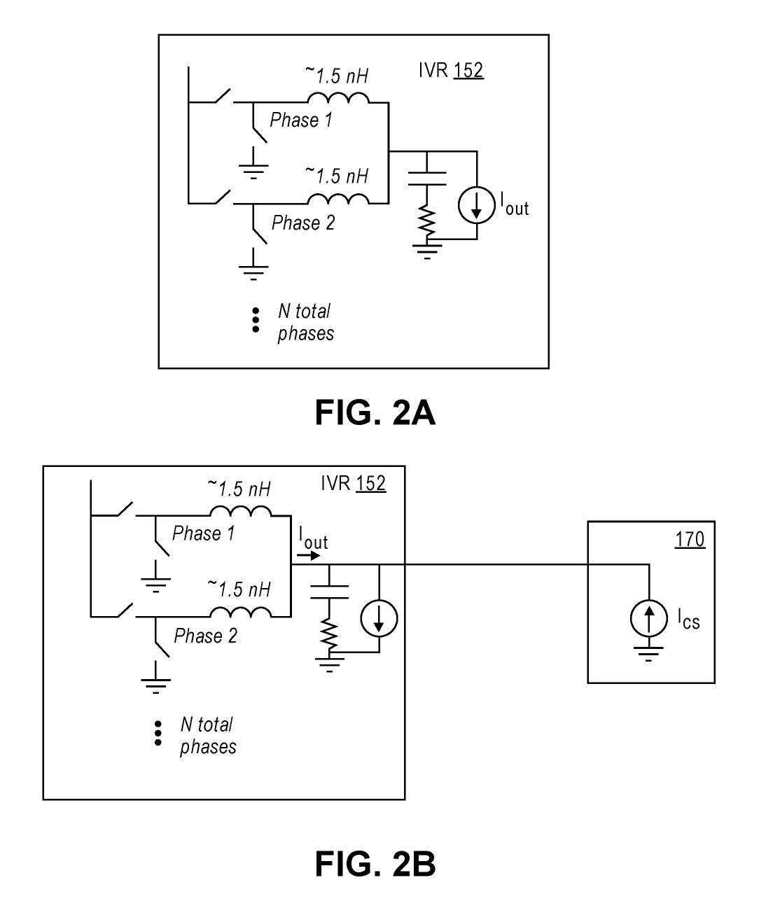

IC 150 is a CPU that includes IVR 152. IVR 152 includes one or more phases (e.g., phase 1-phase N) that provide a voltage stepped down from (or lower than) the voltage provided by VR 110. In one embodiment, the IVR 152 phases increase the current handling capabilities by operating in parallel to provide an output voltage even when the current being consumed by the circuitry on the output is very high. FIG. 2A illustrates one embodiment of a conventional voltage rail implemented at IVR 152. In one embodiment, IVR 152 includes switches implemented as MOSFETs at IC 150, capacitors implemented at IC 150, and inductors implemented on the PCB 100 package.

As shown in FIG. 2A, current drawn by the IC die (e.g., Iₒᵤₜ) is supplied by IVR 152 via inductors and switches. This configuration is typically referred to as a buck regulator. Conventional IVR implementations provide the entire Iₒᵤₜ current, which results in the above-described drawbacks. Referring back to FIG. 1, a PCB current source 170 is provided to one or more voltage rails at PCB 100 to supplement current provided by IVR 152. In one embodiment, current source 170 is a PCB switching power converter that injects current into the IVR 152 output domain via additional pins (discussed in more detail below) at IC 150. In a further embodiment, IC 150 may include many IVR 152 modules, one or more which may have current supplemented by be a current source 170.

In such an embodiment, IVR 152 continues to regulate a rail's voltage in a normal capacity to ensure typical benefits (e.g., fast transient response (particularly on parts where output decoupling is not available), the ability to quickly adjust operating voltage, etc.), while current source 170 provides a low bandwidth current supply that is injected from PCB 100 into the output of the IVR 152 voltage domain. Accordingly, current source 170 does not regulate the output voltage of the supply, which enables FIVR 152 to provide a low, actively regulated output impedance and to change voltages rapidly. For a fixed load current, the amount of low frequency current supplied by IVR 152 is reduced by the amount of current supplied by current source 170. Since current source 170 is not on IC 150, the power it dissipates will not count against the total dissipated power of the IC 150. In a further embodiment, current source 170 may be designed for high efficiency, direct conversion from an input supply (even at 12V), which may allow reduction of the total platform power.

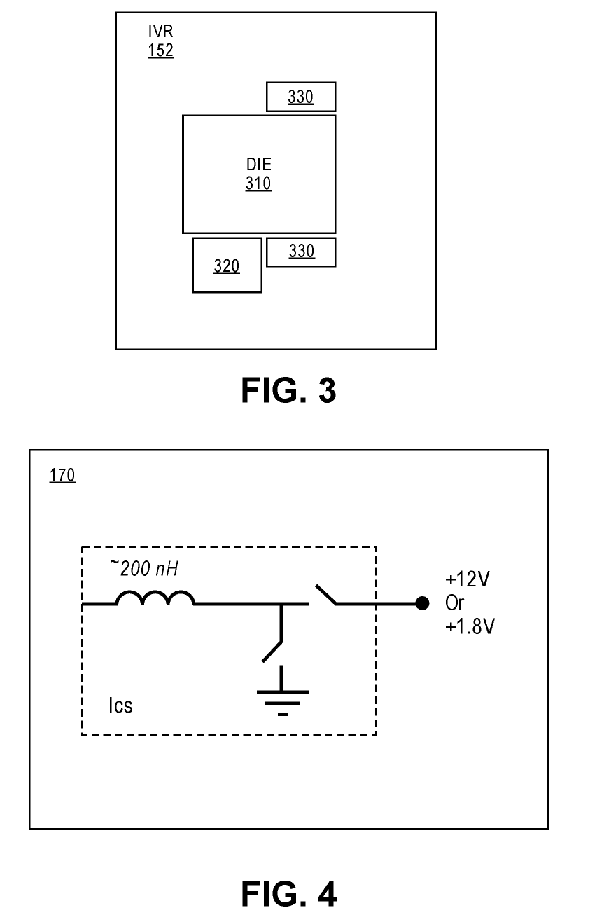

FIG. 3 illustrates one embodiment of IVR 152 packaging configuration for implementation of a current source 170. In one embodiment, IVR 152 includes a die 310 and conventional V_{CCIN} pins 320. In addition, pins 330 are provided to use current source 170. According to one embodiment, a set of pins 330 is included at IVR 152 for each rail that uses current source 170. In such an embodiment, each set of pins 330 is located near the respective IVR 152 rail for which current source 170 is augmenting (or supplementing).

FIG. 2B illustrates one embodiment of a IVR 152 voltage rail augmented with current source 170. In this embodiment, current source 170 supplies I_{CS}, and IVR 152 supplies I_{FIVR}=Iₒᵤₜ−I_{CS}. This provides a substantial reduction in the power dissipated on the IC 250 die by IVR 152. Using the example provided above, if current source 170 sources 15 A of 24 A total current drawn by the IC 250, IVR 152 only needs to supply 9 A. IVR 152 would then be dissipating 1.28 W, resulting in total dissipated power 25.28 W, versus the 28.96 W when the entire current is supplied by FIVR 152. Accordingly, there is a savings of 3.68 W. Moreover, at the same 28.96 W power, IVR 152+current source 170 enables the load to increase to 27 A, versus 24 A with IVR 152 only, which represents a substantial performance improvement in. In a further embodiment, implementation of current source 170 allows for a smaller IVR 152 to meet a given Iₘₐₓ requirement (where Iₘₐₓ is the maximum value Iₒᵤₜ could ever reach). In such an embodiment, IVR 152 only needs to be rated to Iₘₐₓ−I_{CS}.

FIG. 4 illustrates one embodiment of a current source 170 circuit implementation. In one embodiment, configuration represents a buck regulator that configured by control logic (discussed in more detail below) to control the switches in order to output a fixed current. In this embodiment, the bandwidth of IVR 152 is configured to be high enough to filter out ripple current from the current source 170. Other embodiments may feature current source 170 circuit implementations using a variety of different switching or non-switching power converter topologies. Such an embodiment reduces a ripple that has to be filtered by IVR 152, or allow for current source 170 to be shut off rapidly.

Referring back to FIG. 1, current source 170 includes control logic 175 that controls the current provided to augment IVR 152. In one embodiment, control logic 175 is a voltage sensor that monitors the voltage of the IVR 152 plane. In this embodiment, the current supplied by current source 170 is varied as a function of the sensed voltage. For example, current source 170 may be programmed to turn off below a threshold voltage, or to increase current as a linear function of the output voltage. Such an embodiment, would obviate a need for implementation of pins 330, and could potentially operate at high speeds.

In another embodiment, control logic 175 could receive signals from IC 150 power management circuitry (not shown). In such an embodiment, control logic 175 receives signals via an existing power management or system management interface. For example, an existing interface is routed to current source 170. Thus, the current supplied by the current source 170 is programmed by the IC 150 power management circuitry.

In yet another embodiment, one or more dedicated control pins may be added to IC 150 to directly control current source 170. In this embodiment, the pins may provide simple on-off control, or more complicated functionality to dynamically adjust the current provided by current source 170. Current source 170 is thus coupled to the FIVR 152 domain by a number of additional balls or pins on IC 150 selected to meet reliability requirements for handling ICS.

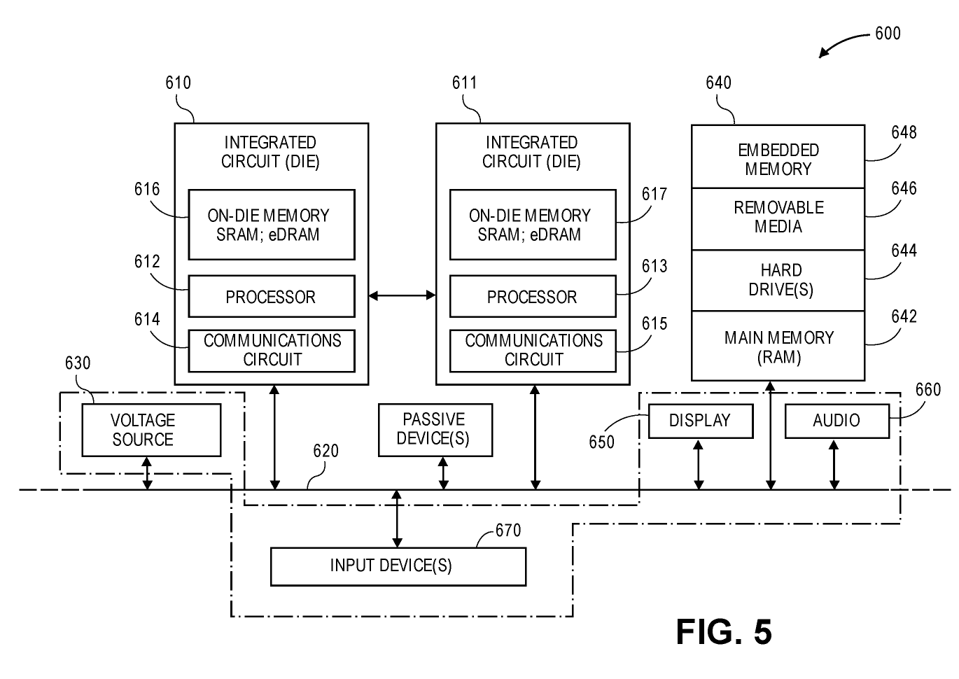

Although described with reference to PCB implementations, current source 170 may be implemented as an external voltage source in other embodiments. FIG. 5 illustrates one embodiment of a computer system 600. The computer system 600 (also referred to as the electronic system 600) as depicted can embody a test system that includes a flip chip package mounted on a test PCB, with a peripheral chip mounted on the flip chip package and a DUT IC coupled to the flip chip package via test probes.

The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 430 supplies current to the integrated circuit 610 through the system bus 620.

The integrated circuit 410 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a micro-controller, a graphics processor, a digital signal processor, or another processor. In an embodiment, the processor 612 includes a flip chip package mounted on a test PCB, with a peripheral chip mounted on the flip chip package and a DUT IC coupled to the flip chip package via test probes.

In an embodiment, SRAM embodiments are found in memory caches of the processor. Other types of circuits that can be included in the integrated circuit 410 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in an embedded TSV die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 470 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a test system that includes a flip chip package mounted on a test PCB, with a peripheral chip mounted on the flip chip package and a DUT IC coupled to the flip chip package via test probes, and their equivalents, an electronic system, a computer system, one or more methods of fabricating an integrated circuit, and one or more methods of fabricating an electronic assembly that includes a semiconductor die packaged according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor die packaged with a thermal interface unit and their equivalents. A foundation substrate may be included, as represented by the dashed line of FIG. 5. Passive devices may also be included, as is also depicted in FIG. 5.

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The following clauses and/or examples pertain to further embodiments or examples. Specifics in the examples may be used anywhere in one or more embodiments. The various features of the different embodiments or examples may be variously combined with some features included and others excluded to suit a variety of different applications. Examples may include subject matter such as a method, means for performing acts of the method, at least one machine-readable medium including instructions that, when performed by a machine cause the machine to performs acts of the method, or of an apparatus or system for facilitating hybrid communication according to embodiments and examples described herein.

Some embodiments pertain to Example 1 that includes a printed circuit board (PCB) comprising an integrated circuit (IC) die having one or more voltage rails and an integrated voltage regulator (IVR) electrically coupled to supply current to a voltage rail, and a PCB current source electrically coupled to supply a supplementary current to the voltage rail.

Example 2 includes the subject matter of Example 1, wherein a magnitude of current supplied to the voltage rail by the IVR is reduced by a magnitude of supplementary current provided by the PCB current source.

Example 3 includes the subject matter of Examples 1 and 2, wherein the IVR comprises one or more pins to couple to the PCB current source.

Example 4 includes the subject matter of Examples 1-3, wherein the PCB current source provides the supplemental current to the voltage rail via the one or more pins.

Example 5 includes the subject matter of Examples 1-4, wherein the PCB current source comprises a switching power converter to generate the supplemental current and control logic to control delivery of the supplemental current by the switching power regulator to the voltage rail.

Example 6 includes the subject matter of Examples 1-5, wherein the control logic comprises a voltage sensor to monitor a voltage provided by the IVR.

Example 7 includes the subject matter of Examples 1-6, wherein the current supplied by the PCB current source is varied as a function of the voltage provided by the IVR that is sensed by the voltage sensor.

Example 8 includes the subject matter of Examples 1-7, wherein the control logic receives one or more signals to supply the supplemental current from IC die power management circuitry.

Example 9 includes the subject matter of Examples 1-8, wherein the control logic is coupled to IC control pins to receive one or more signals to supply the supplemental current from IC die power management circuitry.

Some embodiments pertain to Example 10 that includes a printed circuit board (PCB) current source comprising a power converter to generate a supplemental current source to a voltage rail coupled to an integrated voltage regulator (IVR) and control logic to control delivery of the supplemental current by the power regulator to the voltage rail.

Example 11 includes the subject matter of Example 10, wherein the control logic comprises a voltage sensor to monitor a voltage provided by the IVR.

Example 12 includes the subject matter of Examples 10 and 11, wherein the current supplied by the PCB current source is varied as a function of the voltage provided by the IVR that is sensed by the voltage sensor.

Example 13 includes the subject matter of Examples 10-12, wherein the control logic receives one or more signals to supply the supplemental current from IC die power management circuitry.

Example 14 includes the subject matter of Examples 10-13, wherein the control logic is coupled to IC control pins to receive one or more signals to supply the supplemental current from IC die power management circuitry.

Some embodiments pertain to Example 15 that includes an integrated voltage regulator (IVR) electrically comprising a first set of pins electrically coupled to supply current to a voltage rail and a second set of pins coupled to receive a supplemental current from an external current source.

Example 16 includes the subject matter of Example 15, wherein the supplemental current is supplied to the voltage rail.

Example 17 includes the subject matter of Examples 15 and 16, wherein a magnitude of current supplied to the voltage rail by the IVR is reduced by a magnitude of supplementary current provided by the external current source.

Example 18 includes the subject matter of Examples 15-17, further comprising a first phase to supply the current to the power rail and second phase to supply the current to the power rail.

Some embodiments pertain to Example 19 that includes a printed circuit board (PCB) comprising a voltage regulator an integrated circuit (IC) die coupled to the voltage regulator including one or more voltage rails and an integrated voltage regulator (IVR) electrically coupled to supply current to a voltage rail and a PCB current source electrically coupled to supply a supplementary current to the voltage rail.

Example 20 includes the subject matter of Example 19, wherein a magnitude of current supplied to the voltage rail by the IVR is reduced by a magnitude of supplementary current provided by the PCB current source.

Example 21 includes the subject matter of Examples 19 and 20, wherein the IVR comprises one or more pins to couple to the PCB current source.

Example 22 includes the subject matter of Examples 19-21, wherein the PCB current source provides the supplemental current to the voltage rail via the one or more pins.

Example 23 includes the subject matter of Examples 19-22, wherein the PCB current source comprises a switching power converter to generate the supplemental current and control logic to control delivery of the supplemental current by the switching power regulator to the voltage rail.

Example 24 includes the subject matter of Examples 19-23, wherein the control logic comprises a voltage sensor to monitor a voltage provided by the IVR.

Although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A printed circuit board (PCB), comprising:
one or more voltage rails;
an integrated voltage regulator (IVR) electrically coupled to supply current to a voltage rail; and
a PCB current source electrically coupled to supply a supplementary current to the voltage rail.

2. The PCB of claim 1, wherein a magnitude of current supplied to the voltage rail by the IVR is reduced by a magnitude of supplementary current provided by the PCB current source.

3. The PCB of claim 1, wherein the IVR comprises one or more pins to couple to the PCB current source.

4. The PCB of claim 3, wherein the PCB current source provides the supplemental current to the voltage rail via the one or more pins.

5. The PCB of claim 1, wherein the PCB current source comprises:
a switching power converter to generate the supplemental current; and
control logic to control delivery of the supplemental current by the switching power regulator to the voltage rail.

6. The PCB of claim 5, wherein the control logic comprises a voltage sensor to monitor a voltage provided by the IVR.

7. The PCB of claim 6, wherein the current supplied by the PCB current source is varied as a function of the voltage provided by the IVR that is sensed by the voltage sensor.

8. The PCB of claim 5, wherein the control logic receives one or more signals to supply the supplemental current from IC die power management circuitry.

9. The PCB of claim 5, wherein the control logic is coupled to IC control pins to receive one or more signals to supply the supplemental current from IC die power management circuitry.

10. A printed circuit board (PCB) current source, comprising:
a power converter to generate a supplemental current source to a voltage rail coupled to an integrated voltage regulator (IVR); and
control logic to control delivery of the supplemental current by the power regulator to the voltage rail.

11. The PCB current source of claim 10, wherein the control logic comprises a voltage sensor to monitor a voltage provided by the IVR.

12. The PCB current source of claim 11, wherein the current supplied by the PCB current source is varied as a function of the voltage provided by the IVR that is sensed by the voltage sensor.

13. The PCB current source of claim 10, wherein the control logic receives one or more signals to supply the supplemental current from IC die power management circuitry.

14. The PCB current source of claim 10, wherein the control logic is coupled to IC control pins to receive one or more signals to supply the supplemental current from IC die power management circuitry.

15. An integrated voltage regulator (IVR) electrically, comprising:
a first set of pins electrically coupled to supply current to a voltage rail; and
a second set of pins coupled to receive a supplemental current from an external current source.

16. The IVR of claim 15, wherein the supplemental current is supplied to the voltage rail.

17. The IVR of claim 15, wherein a magnitude of current supplied to the voltage rail by the IVR is reduced by a magnitude of supplementary current provided by the external current source.

18. The IVR of claim 17 further comprising:
a first phase to supply the current to the power rail; and
second phase to supply the current to the power rail.

19. A printed circuit board (PCB), comprising:
a voltage regulator;
an integrated circuit (IC) die coupled to the voltage regulator, including:
one or more voltage rails; and
an integrated voltage regulator (IVR) electrically coupled to supply current to a voltage rail; and
a PCB current source electrically coupled to supply a supplementary current to the voltage rail.

20. The PCB of claim 19, wherein a magnitude of current supplied to the voltage rail by the IVR is reduced by a magnitude of supplementary current provided by the PCB current source.

21. The PCB of claim 19, wherein the IVR comprises one or more pins to couple to the PCB current source.

22. The PCB of claim 21, wherein the PCB current source provides the supplemental current to the voltage rail via the one or more pins.

23. The PCB of claim 19, wherein the PCB current source comprises:
a switching power converter to generate the supplemental current; and
control logic to control delivery of the supplemental current by the switching power regulator to the voltage rail.

24. The PCB of claim 23, wherein the control logic comprises a voltage sensor to monitor a voltage provided by the IVR.
